(19) United States
(12) Patent Application Publication
(10) Pub. No.: US 2003/0015795 A1
(43) Pub. Date: Jan. 23, 2003

(54) Holding apparatus with diffusion barrier layer for semiconductor devices

(76) Inventor: Andreas Kyek, Sinzing (DE)

Correspondence Address: LERNER AND GREENBERG, P.A., Post Office Box 2480, Hollywood, FL, 33022-2480, US

(21) Appl. No.: 10/198,574

(22) Filed: Jul. 18, 2002

(30) Foreign Application Priority Data
Jul. 18, 2001 (DE) 101 34 900.9

(51) Int. Cl. H01L 21/4763; H01L 23/48; H01L 29/40

(52) U.S. Cl. 257/751; 257/750; 257/915; 438/627; 438/643; 438/653

(57) ABSTRACT

The holding apparatus is configured to hold one or more semiconductor devices. An added diffusion barrier layer prevents the diffusion of atoms out of a base body of the holding apparatus into a semiconductor layer and therefore into the semiconductor device.

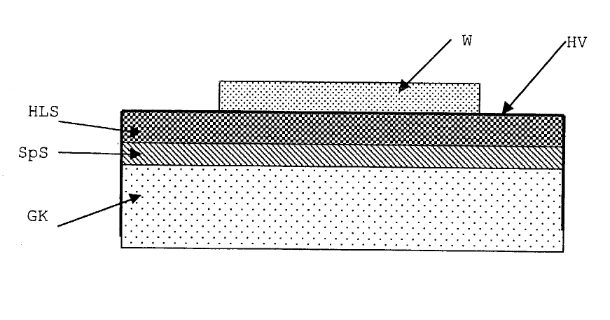

### BACKGROUND OF THE INVENTION

1. Field of the Invention

The present invention relates to a holding apparatus for at least one semiconductor device, comprising a base body with a surface that is equipped to hold the semiconductor device. The invention also relates to a process for producing a holding apparatus of this type.

During production processes to which the semiconductor device is subjected, the semiconductor device is held by a holding apparatus.

Atoms can pass from the holding apparatus into the semiconductor device as a result of solid-state diffusion. In the semiconductor device, the atoms which have passed over act as impurities and impair the quality of products produced from the semiconductor device.

This applies in particular to holding apparatus made from aluminum and a semiconductor device made from silicon, since aluminum has a relatively good mobility in silicon.

To reduce the diffusion of aluminum atoms into the semiconductor device, it is customary for the holding apparatus to be provided with a covering layer of silicon.

This is described, for example, in the Custom Report produced by EATON, “Siemens Microelectronics Center Silicon Coated Disk Qualification.”. The report describes a reduction in the contamination to a silicon wafer by aluminum when silicon-coated holding apparatus made from aluminum are used compared to the use of holding apparatus which are not coated with silicon in ion implantation installations.

However, it has been established that after silicon-coated holding apparatus have been used for a number of months, the contamination of wafers increases again. This is attributable to the fact that aluminum atoms pass out of the holding apparatus into the silicon of the covering layer as a result of solid-state diffusion, and in the covering layer they slowly migrate toward the surface of the covering layer. As soon as this is reached, the same mechanism causes the aluminum atoms to pass from the covering layer on the holding apparatus into the wafer.

### SUMMARY OF THE INVENTION

It is accordingly an object of the invention to provide a holding apparatus with a diffusion barrier layer for semiconductor installations, which overcomes the above-mentioned disadvantages of the heretofore-known devices and methods of this general type and which provides for a device and a process for producing a device that prevents atoms from diffusing out of the holding apparatus into the semiconductor device held in the holding apparatus.

With the foregoing and other objects in view there is provided, in accordance with the invention, a holding apparatus for at least one semiconductor device, comprising:

a base body formed with a surface configured to hold the semiconductor device;

a diffusion barrier layer at least partially covering regions of the surface of the base body that make contact with the semiconductor device; and

an additional covering layer of silicon on at least parts of the diffusion barrier layer and/or parts of the regions of the surface of the base body that are not covered by the diffusion barrier layer.

With the above and other objects in view there is also provided, in accordance with the invention, a method of producing a holding apparatus for one or more semiconductor devices. The method comprises:

providing a base body with a surface equipped to receive the semiconductor device;

applying a diffusion barrier layer at least to parts of those regions of the surface of the base body that make contact with the semiconductor device; and

applying an additional covering layer of silicon at least to parts of the diffusion barrier layer and/or parts of those regions of the surface of the base body that are not covered by the diffusion barrier layer.

In other words, the objects of the invention are achieved with a layer that acts as a diffusion barrier at that surface of the holding apparatus which is equipped to hold the semiconductor device.

In a particularly preferred embodiment of the invention, a further covering layer, preferably comprising a semiconductor material, is applied to this diffusion barrier layer.

The inventive embodiment of the holding apparatus is particularly suitable as a holding apparatus for wafers on ion implantation installations.

Nitrides, i.e. tungsten nitride and titanium nitride, and metal oxides are particularly suitable materials for the diffusion barrier layer.

The diffusion barrier layer is applied to the base body of the holding apparatus. It is preferable for a further covering layer comprising a semiconductor material to be applied to the diffusion barrier layer.

Other features which are considered as characteristic for the invention are set forth in the appended claims.

Although the invention is illustrated and described herein as embodied in a holding apparatus with a diffusion barrier layer for holding a semiconductor device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawing.

### BRIEF DESCRIPTION OF THE DRAWING

The sole figure of the drawing is a diagrammatic sectional side view of a holding apparatus according to the invention.

### DESCRIPTION OF THE PREFERRED EMBODIMENTS

Referring now to the figure of the drawing in detail, there is shown a holding apparatus HV, the base body GK of which, comprising aluminum, is covered, on the surface which faces a semiconductor device W made from silicon, with a diffusion barrier layer SpS. The barrier layer SpS in turn is covered with a covering layer HLS.

The material of the covering layer HLS is silicon. The diffusion barrier layer SpS located between the covering layer HLS and the base body GK consists of titanium nitride.

Even a diffusion barrier layer SpS made from titanium nitride which is only a few atom layers thick prevents the diffusion of aluminum atoms from the base body GK into the covering layer HLS.

If the covering layer HLS remains free of aluminum atoms, there is also no longer any diffusion of aluminum atoms into the semiconductor device W.

For the sake of simplicity, the figure shows only a single semiconductor device W.

I claim:

1. A holding apparatus for at least one semiconductor device, comprising:
a base body formed with a surface configured to hold the semiconductor device;
a diffusion barrier layer at least partially covering regions of said surface of said base body that make contact with the semiconductor device; and
an additional covering layer of silicon on at least parts of said diffusion barrier layer and/or parts of the regions of said surface of the base body that are not covered by said diffusion barrier layer.

2. The apparatus according to claim 1, wherein the semiconductor device is a wafer and the holding apparatus forms a part of an ion implantation installation.

3. The apparatus according to claim 1, wherein the diffusion barrier layer is formed of a metal nitride.

4. The apparatus according to claim 3, wherein the metal nitride is titanium nitride.

5. The apparatus according to claim 3, wherein the metal nitride is tungsten nitride.

6. The apparatus according to claim 1, wherein the diffusion barrier layer is formed of a metal oxide.

7. A method of producing a holding apparatus for a semiconductor device, which comprises:
providing a base body with a surface equipped to receive the semiconductor device;
applying a diffusion barrier layer at least to parts of those regions of the surface of the base body that make contact with the semiconductor device; and
applying an additional covering layer of silicon at least to parts of the diffusion barrier layer and/or parts of those regions of the surface of the base body that are not covered by the diffusion barrier layer.
